(19) United States
(12) Patent Application Publication
(10) Pub. No.: US 2026/0050718 A1
(43) Pub. Date: Feb. 19, 2026

(54) DIGITAL-PHYSICAL TWIN SYSTEM AND METHOD FOR ENVIRONMENTAL PROCESS MODELING AND FORECASTING

(71) Applicants: Jnaneshwar DAS, Tempe, AZ (US); Saurav KUMAR, Tempe, AZ (US); Nakul GOPALAN, Chandler, AZ (US); Ramón ARROWSMITH, Tempe, AZ (US)

(72) Inventors: Jnaneshwar DAS, Tempe, AZ (US); Saurav KUMAR, Tempe, AZ (US); Nakul GOPALAN, Chandler, AZ (US); Ramón ARROWSMITH, Tempe, AZ (US)

(73) Assignee: Arizona Board of Regents on Behalf of Arizona State University, Scottsdale, AZ (US)

(21) Appl. No.: 19/301,829

(22) Filed: Aug. 15, 2025

Related U.S. Application Data
(60) Provisional application No. 63/684,208, filed on Aug. 16, 2024.

(51) Int. Cl. G06F 30/27; G06Q 10/04; G06Q 50/02

(52) U.S. Cl. CPC G06F 30/27; G06Q 10/04; G06Q 50/02

(57) ABSTRACT

A digital-physical twin system and method for environmental process modeling and forecasting are disclosed. The system includes a digital twin server configured to receive environmental data from a real-world environment, including hyperspectral and spectroscopic imaging, simulate environmental process transitions using a predictive model based on the environmental data, and generate parameters for a physical experiment designed to validate or refine the predictive model. A physical twin device, comprising a scaled and instrumented representation of the real-world environment, is configured to execute the physical experiment under controlled conditions. Experimental data is returned to the digital twin to iteratively refine the predictive model in a closed-loop learning cycle using self-supervised and reinforcement learning. The system supports spatially-spectrally selective experimentation, including fluorescence spectroscopy, to enhance environmental sensing. This architecture enables scalable, sample-efficient modeling of processes such as post-wildfire hydrology, vegetation regrowth, and soil change.

### RELATED APPLICATIONS

This application claims the benefit of U.S. Provisional Patent Application No. 63/684,208, filed Aug. 16, 2024, to Das et al., titled “DIGITAL-PHYSICAL TWIN SYSTEM AND METHOD FOR ENVIRONMENTAL PROCESS MODELING AND FORECASTING,” the entirety of the disclosure of which is hereby incorporated by this reference.

### STATEMENT REGARDING FEDERALLY SPONSORED RESEARCH OR DEVELOPMENT

This invention was made with government support under 80NSSC23PB321 and 80NSSC22PA940 awarded by the National Aeronautical and Space Administration. The government has certain rights in the invention.

### TECHNICAL FIELD

This document relates to a digital-physical twin system and method for environmental process modeling and forecasting.

### BACKGROUND

Environmental modeling plays a critical role in understanding and managing natural systems affected by climate change, natural disasters, and human activity. However, existing modeling approaches face significant limitations in scalability, adaptability, and data efficiency. Traditional models often rely on domain-specific knowledge, large labeled datasets, or computationally intensive simulations, which can hinder their application across diverse environmental contexts. Additionally, high-resolution data sources such as hyperspectral imaging are costly and complex to deploy, and their integration into predictive workflows remains challenging. These constraints limit the ability to rapidly validate and refine environmental models in response to evolving real-world conditions.

### SUMMARY

According to some embodiments, a digital-physical twin modeling system comprises a digital twin server comprising a processor and a memory, the processor configured to receive at least one of ground-based hyper-spectral imaging data, aerial hyper-spectral imaging data, and remote sensing data gathered from a real-world environment, generate an environmental model using the received data, simulate environmental process transitions in the environmental model using a predictive model, and generate parameters for a physical experiment designed to validate or refine the predictive model, and a physical twin device comprising a scaled physical representation of the real-world environment, the physical twin device configured to execute the physical experiment based on the parameters generated by the digital twin server, and collect experimental data describing the outcome of the physical experiment, wherein the processor of the digital twin server is further configured to refine the predictive model using the experimental data, simulate environmental process transitions using the refined predictive model, and generate updated parameters for additional physical experiments in a closed-loop learning cycle.

Particular embodiments may comprise one or more of the following features. The additional physical experiments may be designed using reinforcement learning. The environmental process transitions may comprise at least one of post-wildfire hydrological changes, agricultural disease spread, seismic impacts, vegetation regrowth or erosion, and soil property changes. The processor of the digital twin server may be further configured to create an embedding model that maps frequency bands of hyperspectral images on a multidimensional space using a semantic map, an objective function, and a temporal objective function, use the embedding model to fuse semantic data and raw hyperspectral imaging data, and train the predictive model with the fused data using self-supervision. The physical twin device may comprise a housing comprising an air intake manifold, a water intake manifold, and a fume outtake manifold, a water pump in fluidic communication with a water filter and a water supply, a first gantry comprising a laser and a spray nozzle array in fluidic communication with the water pump, a second gantry comprising an imaging payload and a soil probing payload, and a broad spectrum high-power light source. The digital twin server may be configured to continue the closed-loop learning cycle until the predictive model achieves a desired level of validation. The predictive model may be trained using self-supervised learning.

According to some embodiments, a digital-physical twin modeling system comprises a digital twin server configured to receive environmental data from a real-world environment, simulate environmental process transitions using a predictive model based on the environmental data, and generate parameters for a physical experiment designed to validate or refine the predictive model, and a physical twin device configured to execute the physical experiment based on the parameters generated by the digital twin server, and collect experimental data from the physical experiment, wherein the digital twin server is further configured to refine the predictive model using the experimental data, simulate environmental process transitions using the refined predictive model, and generate updated parameters for additional physical experiments in a closed-loop learning cycle.

Particular embodiments may comprise one or more of the following features. The environmental data may comprise at least one of ground-based hyper-spectral imaging data, aerial hyper-spectral imaging data, and remote sensing data. The physical twin device may comprise a scaled physical representation of the real-world environment. The digital twin server may be configured to continue the closed-loop learning cycle until the predictive model achieves a desired level of validation. The digital twin server may be further configured to generate, using machine learning techniques, an environmental model in which to simulate environmental process transitions. The predictive model may be trained using self-supervised learning.

According to some embodiments, a method for environmental process modeling comprises collecting at least one of ground-based hyper-spectral imaging data, aerial hyper-spectral imaging data, and remote sensing data from a real-world environment, generating an environmental model using the collected data, simulating environmental process transitions in the environmental model using a predictive model, generating parameters for a physical experiment designed to validate or refine the predictive model, executing the physical experiment based on the generated parameters using a physical twin device configured to replicate aspects of the simulation, collecting experimental data from the physical experiment, refining the predictive model using the experimental data, simulating environmental process transitions using the refined predictive model, and generating updated parameters for additional physical experiments in a closed-loop learning cycle.

Particular embodiments may comprise one or more of the following features. The method may further comprise continuing the closed-loop learning cycle until the predictive model achieves a desired level of validation. The method may further comprise generating the environmental model using machine learning techniques. The method may further comprise training the predictive model using self-supervised learning. The method may further comprise using reinforcement learning to design the additional physical experiments. The environmental process transitions may comprise at least one of post-wildfire hydrological changes, agricultural disease spread, seismic impacts, vegetation regrowth or erosion, and soil property changes. The method may further comprise creating an embedding model that maps frequency bands of hyperspectral images on a multidimensional space using a semantic map, an objective function, and a temporal objective function, using the embedding model to fuse semantic data and raw hyperspectral imaging data, and training the predictive model with the fused data using self-supervision.

The foregoing and other aspects, features, and advantages will be apparent from the DESCRIPTION and DRAWINGS, and from the CLAIMS if any are included.

### BRIEF DESCRIPTION OF THE DRAWINGS

Implementations will hereinafter be described in conjunction with the appended and/or included DRAWINGS, where like designations denote like elements.

FIG. 1A illustrates an overview of the architecture of a digital-physical twin modeling system for environmental process modeling according to some embodiments.

FIG. 1B illustrates the hierarchical relationship between the real world, the physical twin, and the digital twin, organized by their respective operational time scales according to some embodiments.

FIG. 2 illustrates a digital-physical twin modeling system for environmental process modeling according to some embodiments.

FIG. 3 illustrates a process flow for generating and refining semantic maps according to some embodiments.

FIG. 4 illustrates a physical twin device for simulating environmental surface processes under controlled laboratory conditions according to some embodiments.

FIG. 5A illustrates a physical twin device of a digital-physical twin modeling system according to some embodiments.

FIG. 5B provides a close-up view of a payload of a physical twin device of a digital-physical twin modeling system according to some embodiments.

FIG. 6A illustrates a top view of a physical twin device of a digital-physical twin modeling system according to some embodiments.

FIG. 6B illustrates a conceptual diagram of a physical twin device used for deep reinforcement and self-supervised learning according to some embodiments.

### DETAILED DESCRIPTION

This disclosure, its aspects and implementations, are not limited to the specific material types, components, methods, or other examples disclosed herein. Many additional material types, components, methods, and procedures known in the art are contemplated for use with particular implementations from this disclosure. Accordingly, for example, although particular implementations are disclosed, such implementations and implementing components may comprise any components, models, types, materials, versions, quantities, and/or the like as is known in the art for such systems and implementing components, consistent with the intended operation.

The word “exemplary,” “example,” or various forms thereof are used herein to mean serving as an example, instance, or illustration. Any aspect or design described herein as “exemplary” or as an “example” is not necessarily to be construed as preferred or advantageous over other aspects or designs. Furthermore, examples are provided solely for purposes of clarity and understanding and are not meant to limit or restrict the disclosed subject matter or relevant portions of this disclosure in any manner. It is to be appreciated that a myriad of additional or alternate examples of varying scope could have been presented, but have been omitted for purposes of brevity.

While this disclosure includes a number of embodiments in many different forms, there is shown in the drawings and will herein be described in detail particular embodiments with the understanding that the present disclosure is to be considered as an exemplification of the principles of the disclosed methods and systems, and is not intended to limit the broad aspect of the disclosed concepts to the embodiments illustrated.

Environmental modeling is essential for understanding and managing natural systems, particularly in response to climate change, natural disasters, and human activities. As the need for accurate models grows, the limitations of existing methods-particularly in scalability and application across diverse contexts-have become increasingly evident.

The prior work in environmental modeling has involved the development and application of various sophisticated methodologies aimed at improving the accuracy and comprehensiveness of environmental process simulations in specific domains. These efforts have primarily focused on the integration of multi-scale and multi-modal data for environmental applications, such as hydrological modeling, vegetation analysis, and hazard response.

The use of hyperspectral and multi-spectral imaging for semantic mapping and environmental process modeling represents a significant advancement in the field. This approach involves capturing detailed spectral data across wide geographic areas to better understand agricultural and hydrological processes. However, these methods are expensive, complicated, and produce extensive high-dimensional data sets that are resource-intensive.

In the domain of hydrological modeling, tools such as the Hydrological Simulation Program—FORTRAN (HSPF) and CE-QUAL-W2 have been employed to simulate the dynamics of water flow, sediment transport, and water quality in complex watershed systems. HSPF integrates a wide array of data to simulate land and water phase processes, while CE-QUAL-W2 specializes in the simulation of water body characteristics such as temperature and chemistry. Despite their comprehensive nature, these models encounter significant scalability issues when applied to larger or more varied environmental settings.

The use of deep learning and photogrammetric techniques for environmental hazard assessment (e.g., tornado damage estimation, post-wildfire analysis, etc.) has introduced new capabilities in environmental modeling. These methods leverage high-resolution imagery and advanced machine learning algorithms to generate detailed semantic maps of affected areas. While these techniques can provide a high degree of accuracy, they are often heavily dependent on large data sets and domain-specific knowledge.

The present disclosure is related to a digital-physical twin system 100 and corresponding method for environmental process modeling and forecasting. The digital-physical twin system 100 facilitates learning environmental process dynamics, including surface processes such as agricultural disease hotspot spread, post-wildfire transition hydrology (e.g., debris flows), and impacts of ground seismicity. The digital-physical twin system 100 and method (hereinafter “system” or “method”) specifically addresses the scalability and transferability challenges inherent to interdisciplinary modeling efforts. According to various embodiments, this digital-physical twin system 100 and method leverages a digital twin 102 (i.e., simulation) and a physical twin 104 (i.e., scaled-down physical experiments) working in tandem.

Advantageous over conventional modeling approaches, the digital-physical twin system 100 and method mitigate the current limitations in environmental process modeling through the use of the physical twin 104 to close the loop on model learning and improvement. This digital-physical twin paradigm enables deep reinforcement and self-supervised learning algorithms to validate the models learned for the digital twin 102 using observations made by the physical twin 104.

The digital-physical twin system 100 and method enables direct engagement with human experts and the execution of real-world experiments to validate models. Furthermore, in some embodiments, the digital-physical twin system 100 may be used to explore novel AI algorithms capable of data fusion and dimensionality reduction, crucial for the timely integration of dynamic high-resolution data into agro-geo-hydrological forecasts. The development of a latent space representation of dynamical systems from high-dimensional observations such as hyperspectral imaging offers a novel pathway to understanding the underlying physical processes that govern earth surface processes.

According to various embodiments, the digital-physical twin system 100 and method are based on the cooperation between three interconnected methodologies focused on advancing the monitoring and analysis of surface processes, such as the aftermath of wildfires, earthquakes, or agricultural diseases. Each of these methodologies provides an output to assist another methodology, and each is able to be improved using the output received.

The first methodology is based on real-world observations and experiments. Information including, but not limited to, aerial and ground-based hyperspectral imaging and other comprehensive environmental data is obtained from surface process phenomenon. The second and third methodologies assist with the deployment of the first methodology, refining what type of data is of greatest use. This is particularly helpful in the case of hyperspectral imaging, whose high cost and technical complexity limit its application. Through the refining process of the digital-physical twin system 100 and method, costly techniques such as hyperspectral imaging can used in a more efficient way.

The second methodology is the digital twin 102, a framework for decision support that employs cutting-edge neural networks for semantic mapping, ground feature analysis, and multisensor spatio-temporal fusion, alongside integration with physics models to accurately simulate environmental changes, according to various embodiments. The digital twin 102 is fed the observations from the first and third methodologies, which are used to validate and refine the various models (e.g., semantic embedding model, predictive model, physical models, etc.).

The third methodology is the physical twin 104, which spans design, validation, and learning processes of physical (scaled down) experimentation. Deep reinforcement and self-supervised learning are used to optimize experimental designs. The digital twin 102 (i.e., the second methodology) provides experiment parameters to be implemented by the physical twin 104. As will be discussed below, the physical twin 104 (i.e., the third methodology) comprises a physical environment for performing these experiments, creating data to be fed back into the digital twin 102.

Together, these methodologies provide a sophisticated, multi-modal approach to environmental monitoring, with a strong emphasis on the application of advanced computational and analytical methods to understand and mitigate the impacts of wildfires, crop disease vectors, and natural hazards such as earthquakes.

In use, the digital-physical twin system 100 encompasses simulation studies, field-scale investigations, and lab-scale experiments. The digital twinning pipeline (e.g., the synergy between the digital twin 102 and the physical twin 104), is used to simulate and analyze surface process transitions under various conditions, incorporating data from aerial and ground-based hyper-spectral imaging and remote sensing. These simulations are used to refine the models continuously, ensuring they accurately represent the complex dynamics of real-world hydrological systems.

Field-scale investigations focus on identified test sites in the real world chosen for their relevance to surface process studies. At the lab scale, a physical twin device 104 for surface process studies may be used to conduct controlled experiments that feed back into and refine the digital twin 102.

According to various embodiments, lab scale surface process transition experiments are conducted in the physical twin 104 to recreate various ground conditions and interventions. The physical twin 104 serves as a crucial testbed for validating digital models and simulations, allowing for precise manipulation of variables and direct observation of outcomes. The insights gained from these lab-scale experiments enable refinement of predictive models of surface process dynamics.

It will be apparent to a person of skill in the art that, while much of the following discussion is focused on the application of the digital-physical twin system 100 and method to the modeling of surface processes, other embodiments may be adapted for use in modeling and forecasting other environmental processes. The present disclosure is thus meant to be illustrative rather than restrictive.

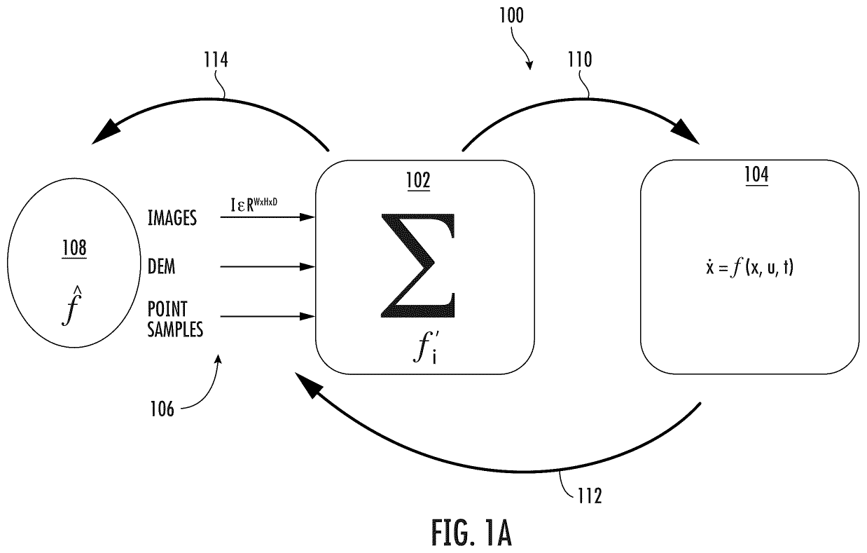

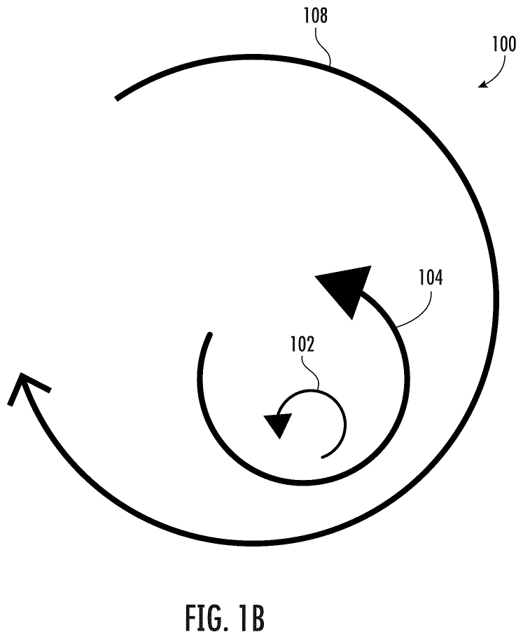

As shown in FIG. 1A, according to some embodiments, the digital-physical twin system 100 comprises a digital twin 102 and a physical twin 104. Field data 106, which may include hyperspectral images, digital elevation models (DEMs), and point samples, may be collected or gathered in a real-world environment 108. Digital elevation models are used to model surface topography, and point samples refer to localized measurements or observations, such as soil moisture readings, temperature, pH levels, or any other environmental variable. The field data 106 may include ground-based hyper-spectral imaging data, aerial hyper-spectral imaging data, and/or remote sensing data. The hyperspectral image data is represented in FIG. 1A as a tensor I∈ [symbol] ^{W×H×D}, where W, H, and D denote the spatial and spectral dimensions. In addition to hyperspectral imaging, spectroscopy, particularly fluorescence spectroscopy, offers a complementary modality for environmental sensing. Fluorescence spectroscopy enables the detection of specific chemical and biological signatures by analyzing the emission spectra of materials excited by controlled light sources. When integrated into the digital-physical twin system 100, this technique can enhance the characterization of surface materials, vegetation health, and soil composition, especially in post-disturbance scenarios such as wildfires or disease outbreaks.

The field data 106 may be provided to the digital twin 102. The digital twin 102 is a computational model that simulates environmental processes based on the field data 106. According to various embodiments, the digital twin 102 analyzes the field data 106 through rapid iterations, bootstrapping from field datasets. In other words, the digital twin 102 starts its learning and simulation cycle using the field data 106, which is real-world data, as a foundation. In some embodiments, the digital twin 102 is configured to process the field data 106 using a set of component models f′ᵢ, which collectively approximate the real-world environmental process denoted by \hat{f}. Thus, the digital twin 102 is configured to receive the field data 106 and generate an environmental model using the field data 106. Once the environmental model is generated, the digital twin 102 may be configured to simulate environmental process transitions in the environmental model using a predictive model. The environmental process transitions may include changes such as post-wildfire hydrological changes, agricultural disease spread, seismic impacts, vegetation regrowth or erosion, and soil property changes.

This is followed by model validation and improvement leveraging the physical twin 104. The digital twin 102 generates parameters 110 for a physical experiment, which are transmitted to the physical twin 104. The physical twin 104 is a laboratory-scale physical model that replicates key aspects of the real-world environment. In some embodiments, the physical experiment is designed to validate or refine the predictive model under controlled conditions. The physical twin 104 is configured to execute the physical experiment (or multiple experiments) based on the parameters 110 generated by the digital twin 102 using a dynamic system model represented by \dot{x}=f(x, u, t), where x is the system state, u is the control input, and t is time. The physical twin 104 is also configured to collect experimental data 112 resulting from the physical experiment that describes the outcome of the physical experiment(s).

The experimental data 112 is returned to the digital twin 102, where the digital twin 102 may use the experimental data 112 for refinement of the predictive model. In some embodiments, the digital twin 102 is configured to simulate environmental process transitions using the refined predictive model and generated updated parameters 110 for additional physical experiments, thus working in a closed-loop learning cycle because the physical experiments inform the predictive model, which is then used to generate parameters 110 for additional experiments. The additional experiments may be designed using reinforcement learning. Additionally, the digital twin 102 may generate field experiment parameters 114 to guide further data collection in the real world, as shown in FIG. 1A. The digital-physical twin system 100 thus supports a closed-loop learning cycle in which the predictive model is continuously refined through iterative simulation, experimentation, and feedback. Finally, the digital-physical twin system 100 may then be used for optimal experiment design for additional collection of field data 106, and the process can repeat. This closed-loop architecture enables efficient, iterative refinement of environmental models while balancing cost, accuracy, and scalability.

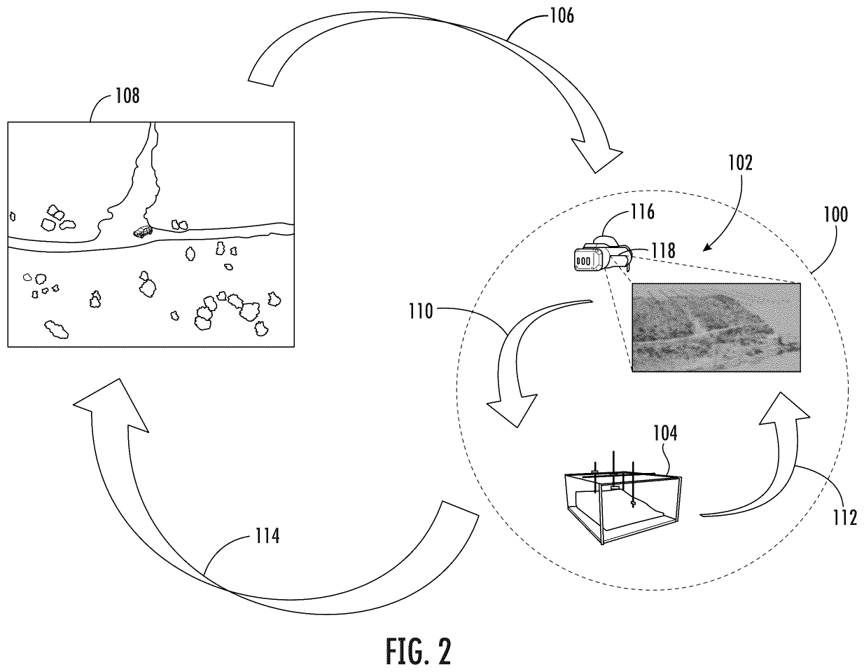

The digital-physical twin paradigm described above is also illustrated in FIGS. 1B and 2. As shown in FIG. 1B, the iterations of refinement and improvement of the models used can be conceptually nested within each other based on their operational time scales, where iterations that involve the real-world environment 108 may be on the scale of weeks to months, iterations that involve the physical twin 104 may be on the scale of minutes to hours, and iterations that involve the digital twin 102 may be on the scale of milliseconds to seconds. This layered structure emphasizes the ability of the digital-physical twin system 100 to simulate and respond to environmental processes across multiple temporal resolutions, enabling rapid iteration and feedback within the digital twin 102 while maintaining alignment with slower real-world dynamics.

Similarly, as shown in FIG. 2, the digital-physical twin system 100 can be used to iterate on the predictive model multiple times before returning back to the real-world environment 108. The digital-physical twin system 100 integrates real-world observations, digital simulations, and scaled physical experiments to optimize environmental modeling and experimental design. The digital twin 102 enables rapid iteration and experimentation in a virtual environment, significantly reducing the need for repeated field deployments. The digital twin 102 is the most cost-effective component of the digital-physical twin system 100, as it relies primarily on computational resources and software infrastructure. The digital twin 102 also serves as the engine for self-supervised learning, generating hypotheses and simulation outputs that inform the design of physical experiments, as explained above. The physical twin 104 is moderately expensive due to the materials, instrumentation, and infrastructure required to construct and operate it. However, the physical twin 104 offers a valuable middle ground between the low-cost, high-speed simulations of the digital twin 102 and the high-cost, high-fidelity observations of the real-world environment 108. Thus, implementing the digital-physical twin system 100 saves on cost by using the most cost-effective tool for each task.

As explained above, the digital-physical twin system 100 helps to reduce the time and resources required to create an accurate predictive model that can be used to understand how real-world environments will behave in the future. The real-world environment is the source of high-fidelity environmental data that results from direct observation and data collection using aerial platforms such as drones, which capture hyperspectral imagery and other field measurements. While this data 106 is critical for grounding the models in real conditions, it is also the most expensive aspect of the system because of the need for specialized equipment, field personnel, and the logistical challenges of accessing remote or hazardous terrain. Thus, a person of skill in the art will recognize that it is beneficial to spend more time within the digital twin 102 and the physical twin 104.

In some embodiments, the digital twin 102, which may be a digital twin server, comprises a processor 116 and a memory 118, and, in some embodiments, the physical twin device 104 comprises a scaled physical representation of the real-world environment 108. The digital twin modeling paradigm centers on the use of neural networks to develop generative models capable of accurately replicating field conditions. These models play a key role in guiding the experimental design for the physical twin 104, ensuring that simulations are both realistic and highly informative for understanding surface process transitions.

Semantic mapping and ground feature analysis make it possible to identify features and phenomenon in hyperspectral data that could be used to model and forecast specific environmental processes. As a specific, non-limiting example, in one embodiment the goal of the semantic mapping and ground feature analysis is to characterize the traits of surficial materials in variably burnt wildfire settings and identify changes on the ground over time after a wildfire event. This information can be used to predict water flows and changes in the development of vegetation over a long horizon of time. This is done by mapping the environment using hyperspectral data and then learning to model the changes in a map over time after a wildfire event.

Hyperspectral data is high dimensional, with a large amount of information per data point. In addition, for some environmental events, such as wildfires, there are relatively few, leading to a small sample size for capturing hyperspectral data related to these events. Modern deep learning based approaches consume internet-scale data and therefore lack sample-efficient techniques to represent and learn from such small samples of high dimensional data.

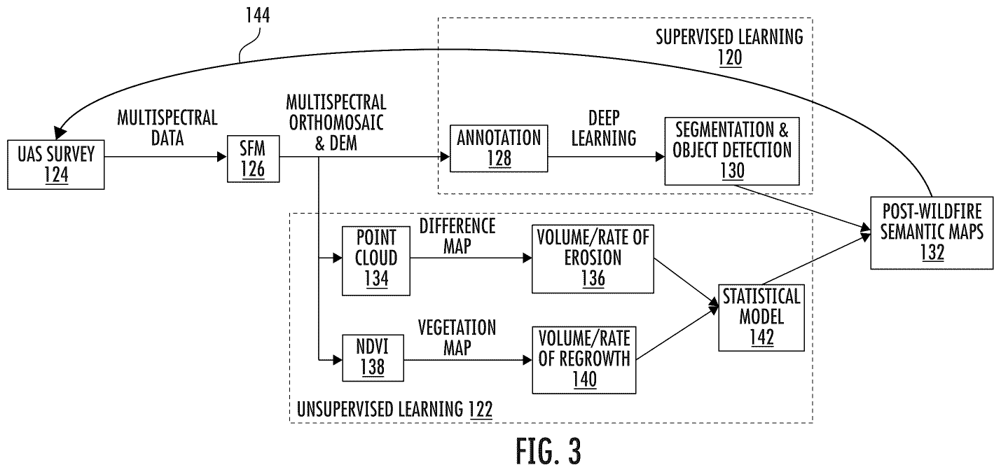

According to various embodiments, the digital twin 102 is configured to utilize efficient deep learning approaches to learn representations and features that would be useful to build a semantic map, as shown in FIG. 3. FIG. 3 is a process flow for developing and refining semantic maps, and specifically illustrates a non-limiting example made specific to the wildfire use case discussed above. FIG. 3 shows a semantic mapping pipeline for field mapping of relevant traits such as rock and vegetation cover and traits, soil hydrophobic properties (e.g., soot), change in rock poses or plant properties, and the like. FIG. 3 outlines both supervised learning pathways 120 and unsupervised learning pathways 122 that contribute to the development of high-resolution, data-driven models of surface process transitions following wildfire events. The process begins with the acquisition of multispectral data via UAS platform 124, which captures detailed imagery of the affected terrain. The collected multispectral data is processed using Structure from Motion (SfM) techniques 126 to generate a multispectral orthomosaic and a digital elevation model (DEM). These outputs are then annotated 128 to identify relevant features such as vegetation types, soil conditions, and burn severity. The annotated data is used to train deep learning models for segmentation and object detection 130, enabling the automated classification of surface features. The results of this pipeline are compiled into semantic maps 132 that represent the spatial distribution of key environmental attributes across the post-wildfire landscape.

In parallel, an unsupervised learning pathway 122 is employed to extract additional insights from the data. Point cloud data is used to generate a difference map 134, which quantifies erosion by calculating changes in surface elevation over time 136. Simultaneously, vegetation indices such as the Normalized Difference Vegetation Index (NDVI) are used to produce vegetation maps 138, which track regrowth dynamics 140. These erosion and regrowth metrics are integrated into a statistical model 142 that supports further analysis of surface process transitions.

The entire workflow is designed to support iterative improvement through sampling strategy optimization 144, which informs the design of future UAS surveys 124. By combining supervised and unsupervised learning techniques, the digital-physical twin system 100 enables efficient, scalable, and accurate modeling of surface process transitions such as post-wildfire environmental changes. This approach enhances the ability to monitor recovery, assess risk, and guide remediation efforts.

Semantic mapping techniques map semantic information from modalities such as language to physical features in the world. Such semantic maps are useful, for example, in the domain of hydro-geology as there is semantic information in the features that are of interest to in-domain experts.

However, the formation of a semantic map for use in a multidisciplinary endeavor is not so straightforward. A challenge here is the lack of information about the features of interest. For example, it is unclear which bands in a hyperspectral data might be of importance to model erosion in early stages immediately after a fire. According to various embodiments, the digital twin 102 employs deep representation learning techniques to learn the features of importance.

Another challenge is the lack of data in many of the domains of interest. The digital twin 102 is configured to map the frequency bands in the hyperspectral images upon a multidimensional embedding space. This is done using the semantic map and an objective function for the neural networks to generate embeddings for every data timestamp. The objective function will have access to some semantic information such as labels about the types of coverage, and types of surface process phenomena of interest, adding structure to the problem.

Additionally, a temporal objective function is used to predict the evolution of the hyperspectral data over time. The temporal objective helps pay attention to the features that cause the change in surface process phenomena, as that would cause the largest change in the feature space.

Advantageously, this is a sample efficient technique. The digital twin 102 can collect high frequency time series data for predictions, with very few labels. The temporal embedding enables tracking of the evolution of hyperspectral bands over time. The change in the embeddings over time may be applied as inputs to machine learning algorithms to discriminate between.

According to various embodiments, a combination of factor graphs and attention based neural networks such as transformers, are leveraged by the digital twin 102 (or the processor 116 of the digital twin 102) use the embedding model to fuse semantic traits and raw hyper-spectral imagery and train the predictive model with the fused data. Self-supervision may be implemented. This enables spatio-temporal prediction of both semantics and spectra. As a result, multi-medium predictive models can be developed and refined from this data. In some embodiments, the digital twin 102 also comprises raw data noise elimination methods. As a specific, non-limiting example, in one embodiment of the digital twin 102, radiance fields methods such as NeRF and Gaussian splatting are adapted to hyper-spectral imagery, and compared with standard structure from motion and feature based techniques for sensor fusion.

The digital twin 102 further comprises one or more physics engines and FEM solvers, according to various embodiments. These physics models may be used to simulate fluid flow, rock/matter transport, debris flow, and the like.

In some embodiments, the digital twin 102 utilizes computational fluid dynamics software (e.g., FLOW-3D, Ansys Fluent, OpenFOAM, etc.), which facilitates the numerical simulation of complex fluid flow and associated physicochemical processes within aqueous systems. This software enables the quantitative analysis of hydrodynamic behavior, sediment transport dynamics, hydraulic loading, and pollutant dispersion in natural and engineered water bodies. Some embodiments of the digital twin 102 integrate the Navier-Stokes equations with models for mass and heat transfer, offering a comprehensive platform for simulating the interaction between fluid phases and the geohydrological impacts of small changes. In some embodiments, the digital twin 102 leverages neural networks to estimate compact lower-dimensional representations of the large spatio-temporal hyperspectral and spectroscopic data, for spatial-spectral data reduction.

The distinction between the digital twin methodology and a computer implementation of the digital twin 102 can be blurry, due to the nature of software. In contrast, the distinction between the physical twin methodology and the implementation of the physical twin 104 is the difference between tangible and intangible.

The physical twin device 104 is a scaled testbed for real world experimentation of processes such as water flow and matter transport. According to various embodiments, the physical twin device 104 facilitates the establishment of appropriate initial conditions with respect to topography, soil moisture level, and compactness. The device 104 is engineered to create changes in soil by creating proxy forest fires on a representative biomass. The digital-physical twin system 100 is informed by field observations of real-world events and informs optimal design for field experiments, to decrease research and management cost.

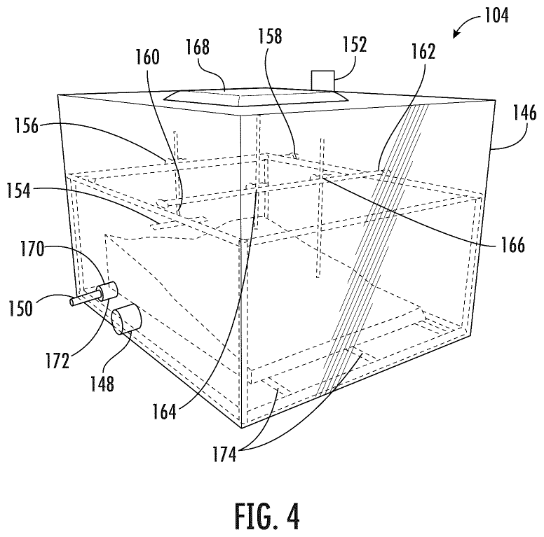

FIG. 4 is a rendering of a non-limiting example of a physical twin device 104, configured for post-wildfire hydrological analysis. As shown, the physical twin device 104 comprises a housing 146 that integrates an air intake manifold 148 and a water intake manifold 150 along with a fume outtake manifold 152. The air intake 148 and the water intake 150 are configured to simulate atmospheric and precipitation conditions, respectively. The fume outtake 152 is connected to a fume hood system to safely vent combustion byproducts or other airborne particulates generated during experiments, such as those involving fire events. Furthermore, the physical twin device 104 comprises a mechanism, such as a water pump 170 in fluidic communication with a water filter 172 and a water supply 174, where water is recirculated after filtration, enabling the simulation of rain events via a spray nozzle array 154 mounted as a payload 156 along a first movable gantry 158. The spray nozzle array 154 may be in fluidic communication with the water pump 170. The payload 156 along the first gantry 158 also houses a laser source 160 for the initiation of localized fire scenarios, according to various embodiments.

In some embodiments, a second movable gantry 162 is equipped with an imaging payload 164 and a soil probing payload 166. The imaging payload 164 may be designed to accommodate a hyper-spectral imager, additional cameras, and/or spectrometers for aerial or ground-based mapping and sampling tasks guided by the digital twin 102. The soil-probing payload 166 may be outfitted with instruments to measure volumetric soil moisture, temperature, and pH, providing an in-depth analysis of soil conditions. The setup is modular and can be adapted to simulate different terrain profiles, moisture levels, and flow conditions. The physical twin device 104 also comprises a light source 168. In some embodiments, the light source 168 is broad spectrum and high-power. In some embodiments, the light source 168 has been characterized with a reflectance target, for precise hyper-spectral imaging in the physical twin 104 and illumination of the testbed surface.

In some embodiments, the physical twin device 104 comprises a spatially-spectrally selective light source, such as a high-lumen projector with UV capabilities. By removing UV protection or using UV-enhanced projectors, the system can perform spatially-selective fluorescence spectroscopy experiments. This setup allows targeted excitation of surface materials within the testbed, enabling fine-grained analysis of fluorescence responses. Such experiments are particularly valuable in precision agriculture and post-wildfire soil analysis, where fluorescence signatures can reveal nutrient levels, contamination, or regrowth dynamics.

As a specific example, in one embodiment the housing 146 may be 5 m×4 m×4 m. According to various embodiments, the first gantry 158 and the second gantry 162 may be robotic, able to be positioned programmatically. As an option, in some embodiments, the digital twin 102 may be configured to prepare sets of specific instructions that are carried out automatically by the gantries 158, 162 and their payloads.

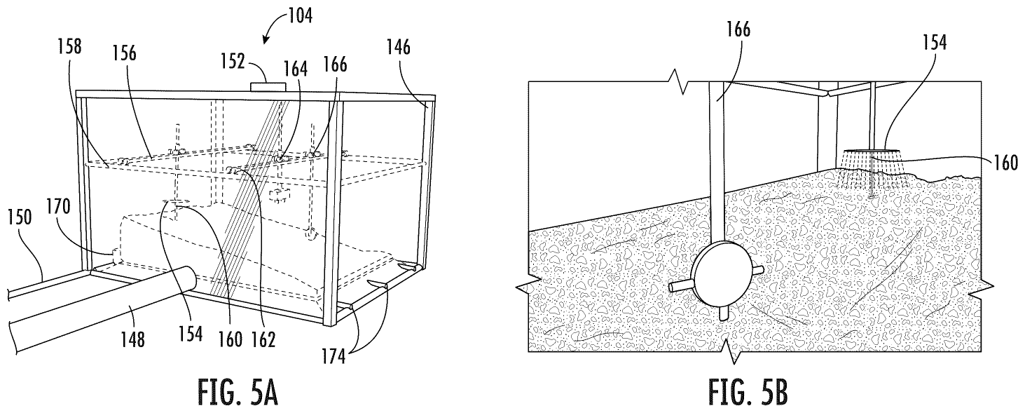

FIGS. 5A and 5B illustrate a non-limiting example of a physical twin device 104. The physical twin 104 is designed to support automated and programmable experimentation, including the simulation of rain, fire, and other environmental stressors. It enables the collection of high-resolution physical data under controlled conditions, which can be used to validate and refine predictive models developed by the digital twin 102. The integration of environmental control systems and sensing infrastructure within a compact, enclosed space allows for efficient, repeatable, and cost-effective experimentation that complements field data collection and digital simulation.

As previously discussed, the digital-physical twin system 100 and method makes use of simulation studies, field-scale investigations, and lab-scale experiments. A robust digital twinning pipeline is used to conduct simulation studies. Field-scale investigations will focus on specific test sites chosen for their relevance to surface process studies, with the field investigations informed by the digital-physical twin system 100. At the lab scale, a physical twin 104 is used for surface process studies where controlled experiments are conducted, and observations are made that are feed back into the digital twin 102.

Artificial intelligence, robotics, and digital-physical system communities have successfully applied deep reinforcement learning and self-supervised learning in a variety of domains ranging from AlphaGo, robot learning for complex manipulation and navigation tasks, and even optimization of energy grid. The digital-physical twin system 100 can leverage this paradigm to carry out self-supervised experimentation where the digital twin 102 optimizes experimental design for the physical twin 104, and the data from the physical experiments are used for parameter updates for the next learning iteration, for model improvement. In some embodiments, the digital twin 102 is configured to continue the closed-loop learning cycle until the predictive model achieves a desired level of validation.

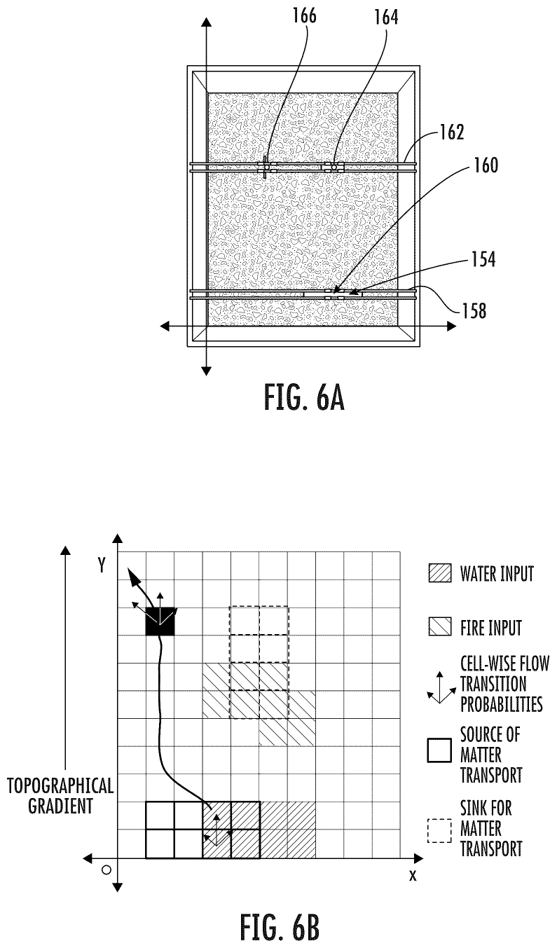

FIG. 6A shows a top view of a non-limiting example of a physical twin 104 capable of simulating fire and rain scenarios. FIG. 6B shows a representation of the physical twin 104 of FIG. 6A adapted for use with deep reinforcement and self-supervised learning. According to various embodiments, the digital twin 102 and the physical twin 104 can work together to conduct self-supervised experiments. This allows them to learn representations and surface process models for a larger scale environment based on a closed lab environment where the rain and fire can be controlled at a much faster rate.

The integration of fluorescence spectroscopy into the closed-loop learning cycle may further expand the system's experimental capabilities. By incorporating spectroscopic feedback, such as fluorescence intensity and spectral shifts, into the reinforcement learning framework, the digital twin 102 can optimize experimental parameters for the physical twin 104. This enables adaptive experimentation where the system learns which spectral regions and excitation patterns yield the most informative data, improving model accuracy and sample efficiency.

Reinforcement learning has been previously used on images at a pixel level to control a robot to solve “pick and place” tasks. The digital-physical twin system 100 and method use similar strategies to model physical phenomena.

According to various embodiments, real hyperspectral data is collected and replicated inside the physical twin 104 by using imitation learning and deep reinforcement learning based techniques. These methods are limited to modeling the actions that already happened in the real world. The system yet lacks the consequences of the actions; this is addressed by the surface process model learned with self-supervision.

A predictive model (e.g., a surface process models of water flow, etc.) is learned through self-supervision using both real world and the physical twin data. In some embodiments, the surface process model is able to predict the flow as it occurs in nature, and other surface process data in nature could be modeled with this surface process model. The digital-physical twin system 100 and method facilitates the creation of more data indoors that would match a real-world environment 108, without spending as much time externally. This will drastically reduce a significant cost for the entire research community.

The present disclosure is related to a method for environmental process modeling. In some embodiments, a method for environmental process modeling is implemented using the digital-physical twin system 100 described herein. The method begins with the collection of environmental data from a real-world site, including ground-based hyperspectral imaging, aerial hyperspectral imaging, and/or remote sensing data. This data is used to generate an environmental model, which serves as the basis for simulating environmental process transitions using a predictive model. Parameters are generated for a physical experiment designed to validate or refine the predictive model. The physical experiment is executed using a physical twin device 104 configured to replicate relevant aspects of the simulated environment. Experimental data collected from the physical twin 104 is used to refine the predictive model, which is then used to simulate updated environmental transitions and generate new parameters for additional physical experiments. This process is repeated in a closed-loop learning cycle.

In some embodiments, the method continues until the predictive model achieves a desired level of validation. The environmental model may be generated using machine learning techniques, and the predictive model may be trained using self-supervised learning. Reinforcement learning may be used to optimize the design of subsequent physical experiments. The environmental process transitions modeled by the system may include post-wildfire hydrological changes, agricultural disease spread, seismic impacts, vegetation regrowth or erosion, and soil property changes. In certain implementations, the method further includes creating an embedding model that maps frequency bands of hyperspectral images onto a multidimensional space using a semantic map, an objective function, and a temporal objective function. This embedding model may be used to fuse semantic data and raw hyperspectral imaging data, and to train the predictive model using self-supervision.

It will be understood that implementations are not limited to the specific components disclosed herein, as virtually any components consistent with the intended operation of a digital-physical twin system and method for environmental process modeling and forecasting may be utilized. Accordingly, for example, although particular systems, methods, and/or devices for environmental process modeling and forecasting may be disclosed, such components may comprise any shape, size, style, type, model, version, class, grade, measurement, concentration, material, weight, quantity, and/or the like consistent with the intended operation of a digital-physical twin system and method for environmental process modeling and forecasting may be used. In places where the description above refers to particular implementations of a digital-physical twin system and method for environmental process modeling and forecasting, it should be readily apparent that a number of modifications may be made without departing from the spirit thereof and that these implementations may be applied to other modeling and forecasting systems and methods.

We claim:

1. A digital-physical twin modeling system, comprising:
a digital twin server comprising a processor and a memory, the processor configured to:
receive at least one of ground-based hyper-spectral imaging data, aerial hyper-spectral imaging data, and remote sensing data gathered from a real-world environment;
generate an environmental model using the received data;
simulate environmental process transitions in the environmental model using a predictive model; and
generate parameters for a physical experiment designed to validate or refine the predictive model; and
a physical twin device comprising a scaled physical representation of the real-world environment, the physical twin device configured to:
execute the physical experiment based on the parameters generated by the digital twin server; and
collect experimental data describing the outcome of the physical experiment;
wherein the processor of the digital twin server is further configured to refine the predictive model using the experimental data, simulate environmental process transitions using the refined predictive model, and generate updated parameters for additional physical experiments in a closed-loop learning cycle.

2. The digital-physical twin modeling system of claim 1, wherein the additional physical experiments are designed using reinforcement learning.

3. The digital-physical twin modeling system of claim 1, wherein the environmental process transitions comprise at least one of post-wildfire hydrological changes, agricultural disease spread, seismic impacts, vegetation regrowth or erosion, and soil property changes.

4. The digital-physical twin modeling system of claim 1, wherein the processor of the digital twin server is further configured to:
create an embedding model that maps frequency bands of hyperspectral images on a multidimensional space using a semantic map, an objective function, and a temporal objective function;
use the embedding model to fuse semantic data and raw hyperspectral imaging data; and
train the predictive model with the fused data using self-supervision.

5. The digital-physical twin modeling system of claim 1, wherein the physical twin device comprises:
a housing comprising an air intake manifold, a water intake manifold, and a fume outtake manifold;
a water pump in fluidic communication with a water filter and a water supply;
a first gantry comprising a laser and a spray nozzle array in fluidic communication with the water pump;
a second gantry comprising an imaging payload and a soil probing payload; and
a broad spectrum high-power light source.

6. The digital-physical twin modeling system of claim 1, wherein the digital twin server is configured to continue the closed-loop learning cycle until the predictive model achieves a desired level of validation.

7. The digital-physical twin modeling system of claim 1, wherein the predictive model is trained using self-supervised learning.

8. A digital-physical twin modeling system, comprising:
a digital twin server configured to:
receive environmental data from a real-world environment;
simulate environmental process transitions using a predictive model based on the environmental data; and
generate parameters for a physical experiment designed to validate or refine the predictive model; and
a physical twin device configured to:
execute the physical experiment based on the parameters generated by the digital twin server; and
collect experimental data from the physical experiment;
wherein the digital twin server is further configured to refine the predictive model using the experimental data, simulate environmental process transitions using the refined predictive model, and generate updated parameters for additional physical experiments in a closed-loop learning cycle.

9. The digital-physical twin modeling system of claim 8, wherein the environmental data comprises at least one of ground-based hyper-spectral imaging data, aerial hyper-spectral imaging data, and remote sensing data.

10. The digital-physical twin modeling system of claim 8, wherein the physical twin device comprises a scaled physical representation of the real-world environment.

11. The digital-physical twin modeling system of claim 8, wherein the digital twin server is configured to continue the closed-loop learning cycle until the predictive model achieves a desired level of validation.

12. The digital-physical twin modeling system of claim 8, wherein the digital twin server is further configured to generate, using machine learning techniques, an environmental model in which to simulate environmental process transitions.

13. The digital-physical twin modeling system of claim 8, wherein the predictive model is trained using self-supervised learning.

14. A method for environmental process modeling, the method comprising:
collecting at least one of ground-based hyper-spectral imaging data, aerial hyper-spectral imaging data, and remote sensing data from a real-world environment;
generating an environmental model using the collected data;
simulating environmental process transitions in the environmental model using a predictive model;
generating parameters for a physical experiment designed to validate or refine the predictive model;
executing the physical experiment based on the generated parameters using a physical twin device configured to replicate aspects of the simulation;
collecting experimental data from the physical experiment;
refining the predictive model using the experimental data;
simulating environmental process transitions using the refined predictive model; and
generating updated parameters for additional physical experiments in a closed-loop learning cycle.

15. The method of claim 14, further comprising continuing the closed-loop learning cycle until the predictive model achieves a desired level of validation.

16. The method of claim 14, further comprising generating the environmental model using machine learning techniques.

17. The method of claim 14, further comprising training the predictive model using self-supervised learning.

18. The method of claim 14, further comprising using reinforcement learning to design the additional physical experiments.

19. The method of claim 14, wherein the environmental process transitions comprise at least one of post-wildfire hydrological changes, agricultural disease spread, seismic impacts, vegetation regrowth or erosion, and soil property changes.

20. The method of claim 14, further comprising:
creating an embedding model that maps frequency bands of hyperspectral images on a multidimensional space using a semantic map, an objective function, and a temporal objective function;
using the embedding model to fuse semantic data and raw hyperspectral imaging data; and
training the predictive model with the fused data using self-supervision.
